(19) United States
(12) Patent Application Publication
(10) Pub. No.: US 2023/0417800 A1
(43) Pub. Date: Dec. 28, 2023

(54) COMBINED SHUNT AND MULTI-SEGMENTED ROGOWSKI-COIL CURRENT SENSOR

(71) Applicant: Tektronix, Inc., Beaverton, OR (US)

(72) Inventors: Josiah A. Bartlett, Forest Grove, OR (US); Daniel G. Knierim, Beaverton, OR (US); David L. Knierim, Wilsonville, OR (US)

(73) Assignee: Tektronix, Inc., Beaverton, OR (US)

(21) Appl. No.: 18/454,035

(22) Filed: Aug. 22, 2023

Related U.S. Application Data
(63) Continuation-in-part of application No. 17/478,738, filed on Sep. 17, 2021, now Pat. No. 11,733,271.
Application No. 17/478,738 is a continuation-in-part of application No. 18/225,034, filed on Jul. 21, 2023.
(60) Provisional application No. 63/083,526, filed on Sep. 25, 2020.
(60) Provisional application No. 63/392,471, filed on Jul. 26, 2022.

(51) Int. Cl. G01R 15/18; G01R 15/14

(52) U.S. Cl. CPC G01R 15/181; G01R 15/146

(57) ABSTRACT

A current sensor configured to measure current in a current-carrying conductor. The current sensor includes a shunt configured to be placed in series with the current-carrying conductor, and a Rogowski coil including at least one conductor segment. The shunt and the Rogowski coil are coupled to produce an output signal representing the current in the current-carrying conductor.

### CROSS-REFERENCES TO RELATED APPLICATIONS

This patent application is a continuation-in-part of U.S. patent application Ser. No. 17/478,738, filed Sep. 17, 2021, which claims the benefit of U.S. Prov. Pat. App. No. 63/083,526, filed Sep. 25, 2020, and a continuation-in-part of U.S. patent application Ser. No. 18/225,034, filed Jul. 21, 2023, which claims the benefit of U.S. Prov. Pat. App. No. 63/392,471, filed Jul. 26, 2022. Each of these previously-filed applications is incorporated into the present disclosure by this reference.

### TECHNICAL FIELD

The subject matter is related to test and measurement systems, and more particularly to devices and methods for measuring electrical current in a device under test.

### BACKGROUND

To measure a current flowing in a device-under-test (DUT), an oscilloscope is often used together with a current probe. The current probe functions as a current sensor, having an input that interfaces or couples with the DUT and an output connected to an input channel of the oscilloscope, and is specifically designed, both physically and electrically, for measuring current.

High-bandwidth current measurements may be difficult to make when such a probe contains a flux concentrator, as this increases self-inductance at the expense of slew rate and loading. A Rogowski coil is a known type of current sensor that offers one solution to this problem.

A conventional Rogowski coil consists of a flexible or rigid conductor in a loop, with a spiral coiled around itself on a closed return path in such a way as to output a voltage that is the derivative of the current passed through the center. The output of the coil is connected to an integrator circuit, which converts the signal to a direct representation of the current.

Conventional Rogowski coils, however, are limited in both sensitivity and bandwidth. The challenge in increasing either sensitivity or bandwidth of a conventional Rogowski coil comes from either overloading the coil insulation due to too much developed voltage, or poor response due to high self-inductance.

Configurations of the disclosed technology address shortcomings in the prior art.

### BRIEF DESCRIPTION OF THE DRAWINGS

FIG. 1 is a graphical representation of a multi-segment Rogowski-coil current sensor substantially surrounding a current-carrying conductor, according to an example configuration.

FIG. 2 is a schematic illustrating an integrator element, according to an example configuration.

FIG. 3 is a schematic illustrating an integrator element configured to accept multiple inputs, according to an example configuration.

FIG. 4 is a schematic illustrating multiple integrator elements coupled to an example of a summing element, according to an example configuration.

FIG. 5 is a schematic illustrating multiple buffers coupled to an example of an integrator, according to an example configuration.

FIG. 6 illustrates an example of an adjustable-length multi-segment Rogowski-coil current sensor, according to an example configuration.

FIG. 7 illustrates the adjustable-length multi-segment Rogowski-coil current sensor of FIG. 6, shown as surrounding a current-carrying conductor that is smaller than the current-carrying conductor shown in FIG. 6, according to an example configuration.

FIGS. 8A to 8C illustrate examples of portions of a multi-segment Rogowski-coil, according to example configurations.

FIG. 9 illustrates an example of a multi-segment Rogowski-coil current sensor that is similar to the multi-segment Rogowski-coil current sensor shown in FIG. 1, except that the output leads of the segments are on the same side of the Rogowski coil, according to an example configuration.

FIG. 10 illustrates an example of a multi-segment Rogowski-coil current sensor in which a first portion is on one side of a printed circuit board and a second portion is on an opposite side of the printed circuit board, according to an example configuration.

FIG. 11 is a flow chart of an example method of using a multi-segment Rogowski-coil current sensor to measure current in a current-carrying conductor, according to example implementations.

FIG. 12 shows a block diagram of a current measurement accessory within a test and

measurement system.

FIGS. 13A-13D show different embodiments of current shunts.

FIGS. 14A and 14B show an embodiment of a current shunt using a Rogowski coil.

FIGS. 15A and 15B show an alternative embodiment of a current shunt using a Rogowski coil.

FIG. 16 shows an embodiment of a current shunt using a Rogowski coil in a bulbar.

FIG. 17 shows an embodiment of a current shunt using a Rogowski coil in a flex circuit embodiment.

### DETAILED DESCRIPTION

As described herein, configurations of the disclosed technology include a Rogowski coil that is in multiple segments. Forming the coil from multiple segments allows for better optimization. Due to linearity and superposition, a Rogowski coil may be made up of several segments. Such segments, as long as collectively they substantially surround the current carrying conductor, will, when summed, produce the equivalent external field rejection of a single-segment Rogowski coil. Furthermore, since the self-resonance of each coil segment will be smaller than a single coil of equivalent dimension, the maximum bandwidth of the current measurement can be higher. The output of each segment is passed into a separate integrator. Since differentiation and integration are both linear operations, the output of each integrator may be summed to produce the equivalent signal of a single coil-integrator combo.

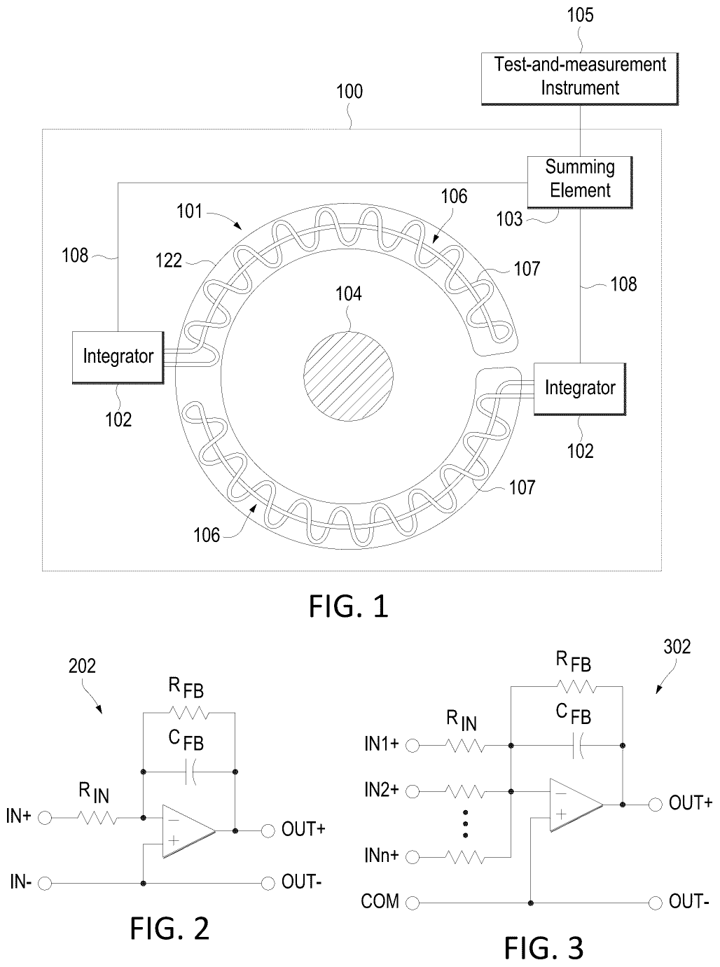

FIG. 1 is a graphical representation of a system that includes a multi-segment Rogowski-coil current sensor 100 (also referred to as current sensor 100 in this disclosure) according to an example configuration. As illustrated in FIG. 1, the current sensor 100 may include a Rogowski coil 101, an integrator element 102, and a summing element 103. The current sensor 100 is configured to measure current in a current-carrying conductor 104, such as a wire or a trace in a printed circuit board, a cross-section of which is shown in FIG. 1. The current sensor 100 may be coupled to a test-and-measurement instrument 105. The test-and-measurement instrument 105 may be, for example, an oscilloscope.

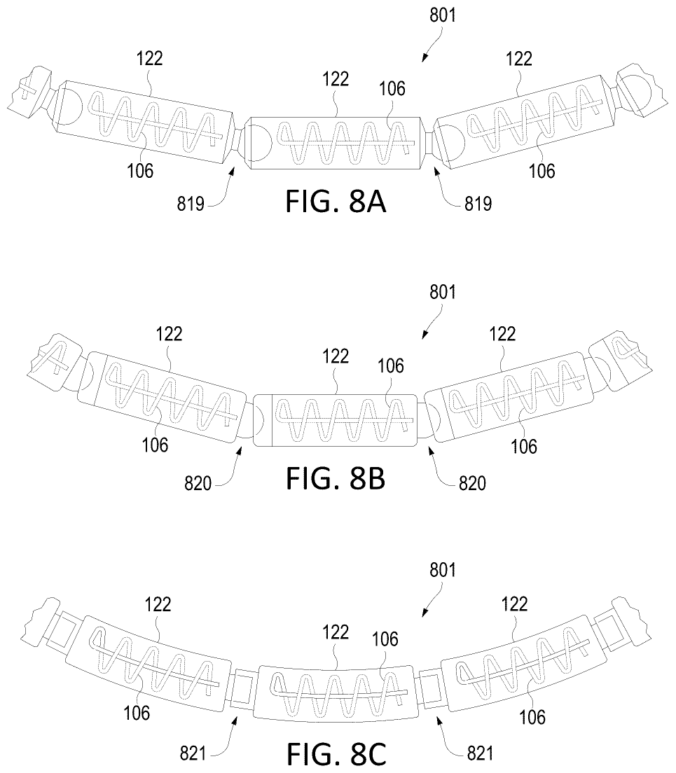

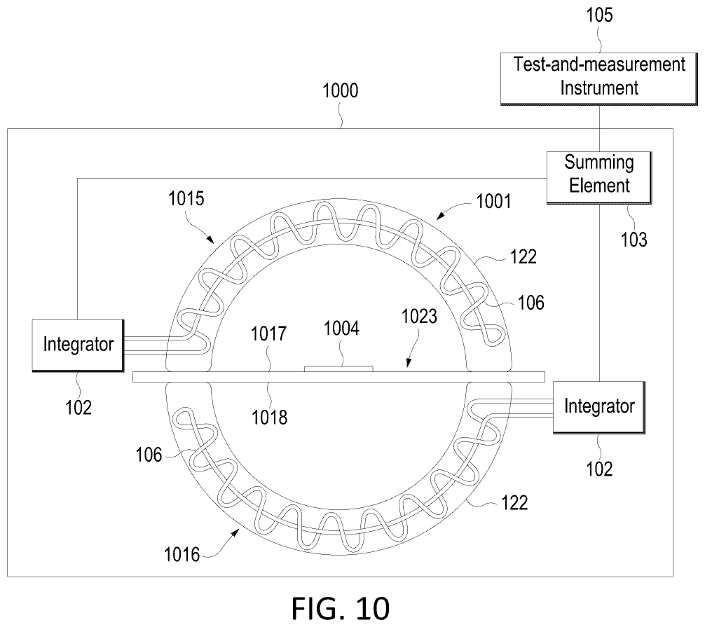

The Rogowski coil 101 includes more than one conductor segment 106, where each segment includes a helically wound wire 107. All examples in this disclosure show each conductor segment including a helically wound wire, but alternative wiring techniques to form a Rogowski coil are also compatible with the disclosed technology. The conductor segments 106 are arranged to form a substantially complete loop, or are positionable to form a substantially complete loop. As used in this disclosure, “substantially complete” means largely or essentially whole, without requiring perfect entireness. For example, in configurations there may be gaps or spaces between adjacent conductor segments 106 as long as, all together, the conductor segments 106 may be positioned to form a loop. Accordingly, the Rogowski coil 101 substantially surrounds the current-carrying conductor 104. As used in this disclosure, “substantially surround” means largely or essentially extending around, without requiring perfect encircling. In some embodiments, the conductor segments 106 are arranged to form more than one substantially complete loops around the current-carrying conductor 104. For example, in some embodiments, multiple conductor segments 106 may each form a substantially complete loop around the current-carrying conductor 104. A conductor segment 106 may have an optimized current measurement frequency range different than other conductor segments 106. The conductor segments 106 may all be the same length, or the conductor segments 106 may have different lengths. The conductor segments 106 may all have the same impedance or inductance, or the conductor segments 106 may have different impedances or inductances. In configurations, each of the conductor segments 106 that make up the Rogowski coil 101 is in a common housing 122, an example of which is shown in FIG. 1. In configurations, the conductor segments 106 that make up the Rogowski coil 101 may be in separate housings 122, examples of which are shown in FIGS. 8A to 8C and FIG. 10. In configurations, the conductor segments 106 that make up the Rogowski coil 101 are electrically isolated from each other, meaning that the conductor segments 106 are not electrically coupled, other than through an integrator element, a summing element, or a buffer element as described in this disclosure.

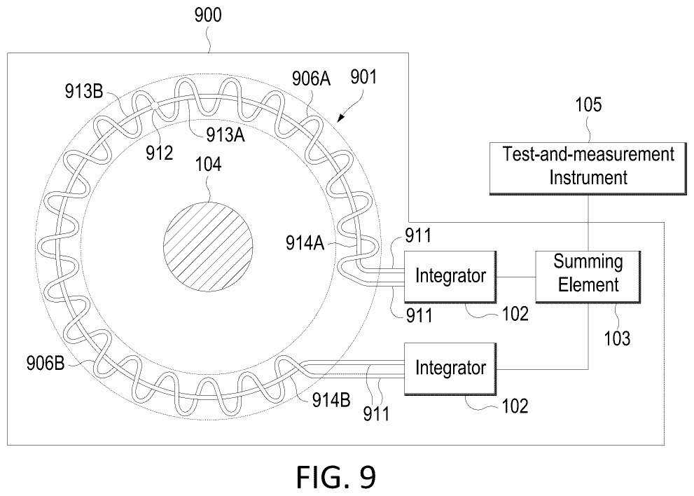

Each conductor segment 106 is configured to provide multiple electrical signals, or a continuous electrical signal, over time. The electrical signal, which may be a voltage signal, is related to the amount of current flowing in the current-carrying conductor 104. Each conductor segment 106 that makes up the Rogowski coil 101 need not be physically separated from each other conductor segment 106 of the Rogowski coil 101 since each conductor segment 106, as a natural result of how it operates, develops an independent electrical signal at its output. Hence, as discussed below for FIG. 9, in configurations adjacent conductor segments 106 may be shorted together.

The summing element 103 is configured to produce a sum of outputs of the individual integrator elements 102 (which are discussed in more detail below). In configurations, the summing element 103 may be, for example, a summing amplifier, implemented either as an analog circuit or as a digital equivalent of an analog summing amplifier. While illustrated in FIG. 1 as being functionally separate from the test-and-measurement instrument 105, in configurations the summing element 103 may be within the test-and-measurement instrument 105.

The integrator element 102 is configured to provide an output signal (represented by pathway 108) that is proportional to electrical current in the current-carrying conductor 104. The integrator element 102 may be an analog circuit element, such as described for FIGS. 2-5 below, or the integrator element 102 may be a digital equivalent of the analog circuit elements described in this disclosure. Each integrator element 102 may include an analog-to-digital converter, either at the inputs side of the integrator (for example, for an integrator element that operates digitally) or at the output side of the integrator (for example, for an analog integrator element whose output signal is passed to a digital circuit element). While illustrated in FIG. 1 as being functionally separate from the test-and-measurement instrument 105, in configurations one or more of the integrator elements 102 may be within the test-and-measurement instrument 105. For each of the circuits illustrated in FIGS. 2-5, the impedance load placed across the coil output may be reconfigurable by, for example, changing the value of the resistor across the coil output.

In configurations, the position of a first conductor segment 106 relative to a second conductor segment 106 may be determined by introducing a signal to the first conductor segment 106 and receiving a corresponding signal from the second conductor element.

FIG. 2 is a schematic of an integrator element 202, according to an example configuration. The integrator element 202 of FIG. 2 may be used for the integrator element 102 described above for FIG. 1. As illustrated in FIG. 2, the integrator element 202 is configured to receive, at inputs of the integrator element 202, an electrical signal output from a single conductor segment 106 of the plurality of conductor segments 106 that make up the Rogowski coil 101. In such configurations, there may be an individual integrator element 202 for each of the conductor segments 106 that make up the Rogowski coil 101.

FIG. 3 is a schematic of an integrator element 302, according to an example configuration. The integrator element 302 of FIG. 3 may be used for the integrator element 102 described above for FIG. 1, including as a replacement for both of the integrator elements 102 illustrated in FIG. 1. As illustrated in FIG. 3, the integrator element 302 is configured to receive, at inputs of the integrator element 302, an electrical signal output from more than one conductor segment 106 of the plurality of conductor segments 106 that make up the Rogowski coil 101. FIG. 3 illustrates that there may be any number of inputs (identified as 1 to n) of the integrator element 302, where each input of the integrator element 302 corresponds to one of the n conductor segments 106. As illustrated in FIG. 3, the conductor segments 106 that are the input sources for the integrator element 302 share a common ground.

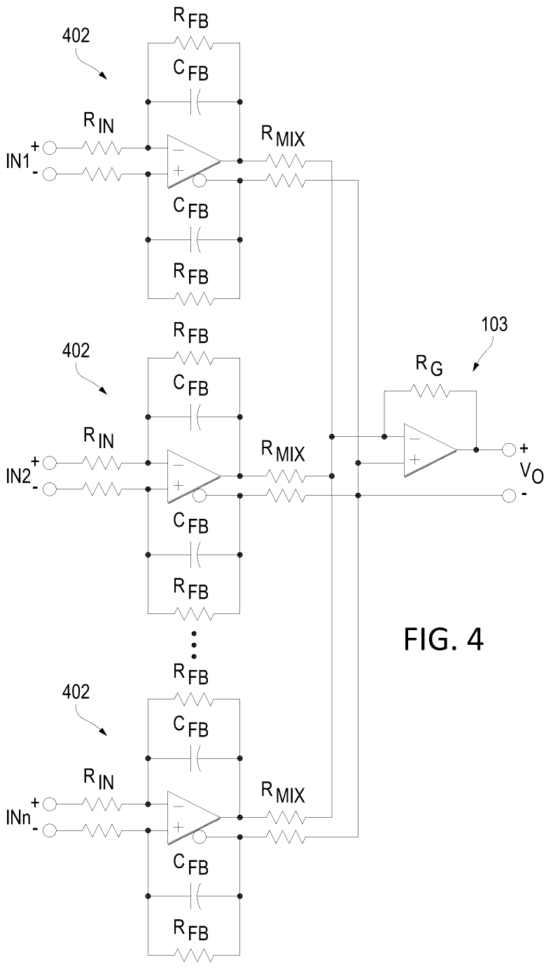

FIG. 4 is a schematic of multiple integrator elements 402 coupled to an example of a summing element 103, according to an example configuration. The integrator elements 402 of FIG. 4 may be used for the integrator elements 102 described above for FIG. 1. As illustrated in FIG. 4, more than one integrator element 402 may be combined with a summing element 103 (which is discussed above for FIG. 1) such that the outputs of the multiple integrator elements 402 are inputs to the summing element 103. The integrator elements 402 illustrated in FIG. 4 may be as described above for the integrator elements 102 of FIG. 1 and the integrator elements 202 of FIG. 2. FIG. 4 illustrates that there may be any number of integrator elements 402 (1 to n), where each integrator element 402 corresponds to one of the n conductor segments 106. In configurations, the inputs to each integrator element 402 are differential, to allow each conductor segment 106 of the Rogowski coil 101 to connect to an individual integrator element 402 without requiring that the conductor segments 106 share a common reference terminal. In configurations where one or more of the conductor segments 106 do share a common terminal, one differential input of each integrator element 402 may be tied to the common reference terminal to reduce wiring complexity.

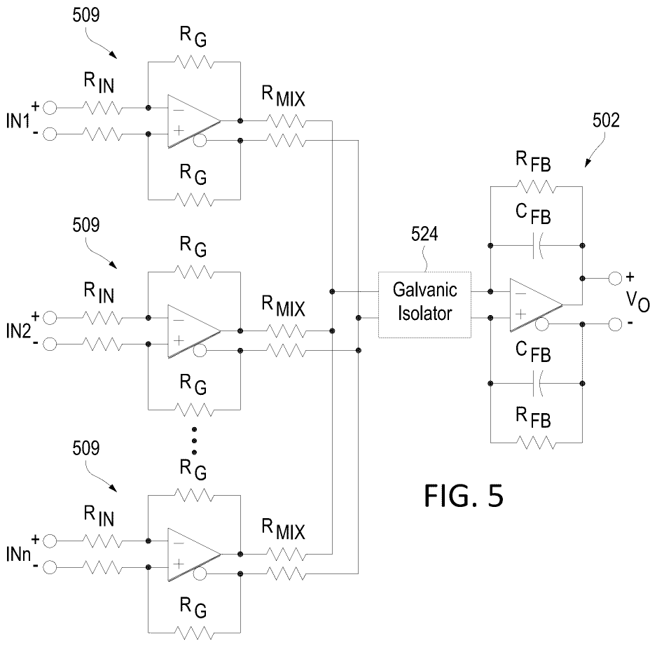

FIG. 5 is a schematic illustrating multiple buffer elements 509 coupled to an example of an integrator element 502, according to an example configuration. The integrator element 502 of FIG. 5 may be used for the integrator element 102 described above for FIG. 1, including as a replacement for both of the integrator element 102 illustrated in FIG. 1. Hence, for example, each conductor segment 106 of the plurality of conductor segments 106 that make up the Rogowski coil 101 may be coupled to a buffer element 509, such that the electrical signal output of the conductor segment 106 is provided to the respective buffer element 509, and the integrator element 502 is configured to receive an output from more than one (including all) of the individual buffer elements 509. This example configuration is one way to electrically isolate several Rogowski coil 101 conductor segments 106 from each other. Electrical isolation may, for example, allow a higher operating bandwidth than in the absence of electrical isolation. Additionally, this example configuration may help improve sensitivity. In versions, the example configuration illustrated in FIG. 5 may include a galvanic isolator 524 configured to prevent a direct conduction path between buffer elements 509 and the integrator element 502. The galvanic isolator 524 may be or include, for example, a transformer or other circuit elements known to provide galvanic isolation.

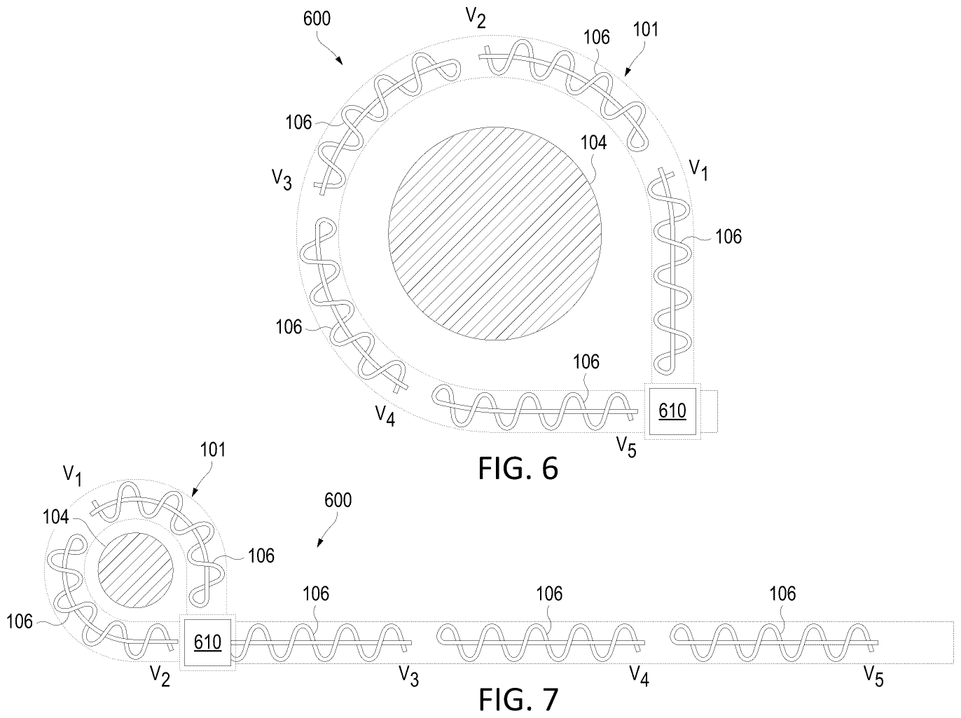

FIG. 6 illustrates an example of an adjustable-length multi-segment Rogowski-coil current sensor 600, according to an example configuration. FIG. 7 illustrates the adjustable-length multi-segment Rogowski-coil current sensor 600 of FIG. 6, shown as surrounding a current-carrying conductor 104 that is smaller than the current-carrying conductor 104 shown in FIG. 6. As illustrated in FIGS. 6-7, the adjustable-length current sensor 600 includes more than one conductor segment 106, each generating a voltage signal. The example voltage signals for the conductor segments 106 are labeled in FIGS. 6-7 as V₁ to V₅. Some or all of the conductor segments 106 of the adjustable-length current sensor 600 form a Rogowski coil 101.

One end of the chain of conductor segments 106 may be coupled to a cinch mechanism 610 configured to mechanically cinch the conductor segments 106 to utilize a desired number of conductor segments 106 to form the Rogowski coil 101. As illustrated in FIG. 7, the cinch mechanism 610 is configured to divide the portion of the conductor segments 106 that comprise the Rogowski coil 101, or loop, (such as those conductor segments 106 corresponding to voltage signals V₁ and V₂ in FIG. 7) and the portion of the conductor segments 106 that are outside of the Rogowski coil 101, or loop, (such as those conductor segments 106 corresponding to voltage signals V₃, V₄, and V₅ in FIG. 7).

The adjustable-length current sensor 600 may further include a detector configured to detect how many conductor segments 106 are forming the Rogowski coil 101. The detector may be or include, for example, a mechanical detector or switch or an optical detector or switch. In addition, or instead, the conductor segments 106 may include a physical identifier or an electronic identifier that is sensed by the detector when the conductor segment 106 passes through or past the detector as the adjustable-length multi-segment Rogowski-coil current sensor 600 is cinched around the current-carrying conductor 104. As an example, where the detector includes an optical detector, the optical detector may be triggered by a pattern, such as a dot code or bar code. Examples utilizing a mechanical detector include a set of contacts brushing against a set of conductors that are configured uniquely for each position, a rotary encoder engaged by gear teeth or a friction mechanism. Other examples of a detector may include an RFID (radio-frequency identification) detector, a Hall sensor, or a potentiometer. In configurations, the detector may be part of the cinch mechanism 610.

By way of example, the detector illustrated in FIG. 6 would detect that five conductor segments 106 make up the Rogowski coil 101 of FIG. 6. And the detector illustrated in FIG. 7 would detect that two conductor segments 106 make up the Rogowski coil 101 of FIG. 7, with the remaining three conductor segments 106 being outside of the Rogowski coil 101 of FIG. 7. The conductor segments 106 outside of the Rogowski coil 101 would be “off” in that their voltage outputs would not be included in the determination of the current flowing through the current-carrying conductor 104. The conductor segments 106 may be “off,” for example, because the conductor segment 106 is ignored by the test-and-measurement instrument 105 or because the conductor segment 106 is electrically isolated from the test-and-measurement instrument 105. Those conductor segments 106 that make up the Rogowski coil 101 would be “on” in that their voltage outputs would be included in the determination of the current flowing through the current-carrying conductor 104. The detector may be configured to allow the chain of conductor segments 106 to slide through or past the detector. In this way, the size of the Rogowski coil 101 may be adjusted to accommodate a relatively larger current-carrying conductor 104, such as shown in FIG. 6, or to accommodate a relatively smaller current-carrying conductor 104, such as shown in FIG. 7. In the illustrated configuration, the adjustment method is similar to how the diameter of the loop of a cable tie, or zip tie, is increased and decreased.

FIGS. 8A to 8C illustrate examples of portions of a multi-segment Rogowski-coil, according to example configurations. More specifically, FIG. 8A to 8C show several conductor segments 106 of the plurality of conductor segments 106 that make up a Rogowski coil 801 of a multi-segment Rogowski-coil current sensor, such as the current sensor 100 discussed above for FIG. 1, the current sensor 600 discussed above for FIG. 6, the current sensor 900 discussed below for FIG. 9, and the current sensor 1000 discussed below for FIG. 10.

As illustrated in FIGS. 8A and 8B, each conductor segment 106 of the plurality of conductor segments 106 may be flexibly joined to an adjacent conductor segment 106. In this context, “flexibly joined” means that the conductor segment 106 can be pivoted or repositioned relative to the adjacent conductor segment 106 while the conductor segment 106 is physically joined to the adjacent conductor segment 106. As examples, the flexible joint could be or include a mechanical snap mechanism 819, such as what is illustrated in FIG. 8A, or a magnetic mechanism 820, such as what is illustrated in FIG. 8B.

In configurations, a conductor segment 106 of the plurality of conductor segments 106 is mechanically separable from the adjacent conductor segment 106 of the plurality of conductor segments 106. In this context, “mechanically separable” means that the conductor segment 106 and the adjacent conductor segment 106 can be separated and moved away from each other without causing permanent damage to either component. As examples, the mechanically separable joint could be or include a mechanical snap mechanism 819 (such as what is illustrated in FIG. 8A), a magnetic mechanism 820 (such as what is illustrated in FIG. 8B), or a plug-and-socket mechanism 821 (such as what is illustrated in FIG. 8C).

Accordingly, a Rogowski coil 801 of any length could be formed by adding or removing conductor segments 106 as needed. Also, the conductor segments 106 may be added in any sequence to form the Rogowski coil 801. The joint configurations illustrated in FIGS. 8A to 8C and discussed here could be used with any of the other configurations described, illustrated, or contemplated by this disclosure.

FIG. 9 illustrates an example of a multi-segment Rogowski-coil current sensor 900 that is similar to the multi-segment Rogowski-coil current sensor 100 of FIG. 1, except that the output leads 911 of each of the conductor segments are on the same side of a Rogowski coil 901 of the multi-segment Rogowski-coil current sensor 900 of FIG. 9. Hence, for example, the Rogowski coil 901 may include a first conductor segment 906A and a second conductor segment 90613. The first conductor segment 906A and the second conductor segment 90613 may be joined at a tie point 912 on a first end 913A, 9138 of each of the first conductor segment 906A and the second conductor segment 90613. Even though the first conductor segment 906A and the second conductor segment 90613 are joined electrically at the tie point 912, the first conductor segment 906A and the second conductor segment 90613 still develop independent differential voltages at their respective outputs leads 911. Shorting the first conductor segment 906A and the second conductor segment 90613 at the tie point 912, however, allows common mode connection between the integrator elements 102. As long as the integrator elements 102 reject any common mode voltages shared by the first conductor segment 906A and the second conductor segment 90613, whether the tie point 912 is shorted together or open does not alter the output of the first conductor segment 906A and the second conductor segment 90613 as measured at the outputs leads 911.

A second end 914A, 91413 of each of the first conductor segment 906A and the second conductor segment 90613 may include the output leads 911. As illustrated in FIG. 9, the output leads 911 may be coupled to an integrator element 102 for each of the first conductor segment 906 and the second conductor segment 90613. Alternatively, any of the integrator configurations discussed above for FIGS. 2-5 may be utilized in place of the integrator elements 102 illustrated in FIG. 9. Configurations where the output leads 911 are on the same side of the Rogowski coil 901 may have the advantage of providing better access to the output leads 911 for connecting the output leads 911 to other devices or circuit elements.

FIG. 10 illustrates an example of a multi-segment Rogowski-coil current sensor 1000 in which a first portion 1015 of a Rogowski coil 1001 of the multi-segment Rogowski-coil current sensor 1000 of FIG. 10 is on a first side 1017 of a printed circuit board 1023 and a second portion 1016 of the Rogowski coil 1001 is on a second, opposite side 1018 of the printed circuit board 1023. In other words, the printed circuit board 1023 is between the first portion 1015 of the Rogowski coil 1001 and the second portion 1016 of the Rogowski coil 1001. Each of the first portion 1015 and the second portion 1016 includes one or more conductor segments 106. As illustrated in FIG. 10, each conductor segment 106 may be coupled to an integrator element 102, which, in turn, are connected to a summing element 103. Alternatively, any of the integrator configurations discussed above for FIGS. 2-5 may be utilized in place of the integrator elements 102 illustrated in FIG. 10.

As illustrated in FIG. 10, configurations of the current sensor 1000 may be used to measure current in a trace 1004 on the printed circuit board 1023. In versions of such configurations, the second portion 1016 of the Rogowski coil 1001 may be permanently built into the printed circuit board 1023. In this context, “permanently” means that the second portion 1016 of the Rogowski coil 1001 is not intended to be removed from the Rogowski coil 1001 during normal operation of the multi-segment Rogowski-coil current sensor 1000 of FIG. 10.

In configurations, one or both of the first portion 1015 and the second portion 1016 of the Rogowski coil 1001 may be clamped around the trace to be measured, may be attached to each other, or may be attached to the printed circuit board 1023, as examples. The attachment may be by, for example, magnets or other connection mechanisms.

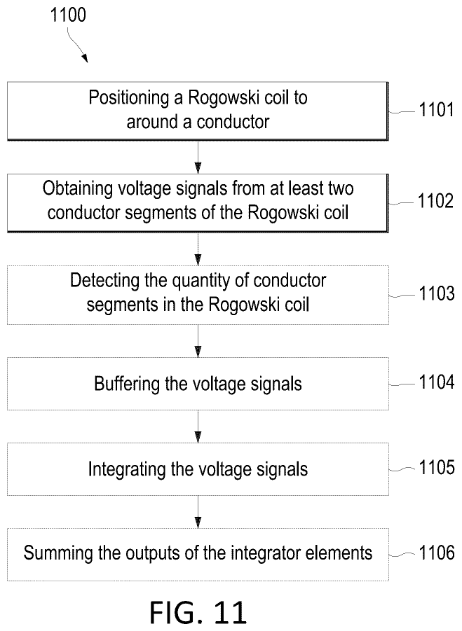

FIG. 11 illustrates an example method of using a current sensor 100 to measure current in a current-carrying conductor 104. As illustrated in FIG. 11, the method 1100 may include positioning 1101 a Rogowski coil 101 to substantially surround a current-carrying conductor 104. The Rogowski coil 101 has plurality of conductor segments 106, and each conductor segment 106 of the plurality of conductor segments 106 includes a helically wound wire 107. The plurality of conductor segments 106 are arranged to form a substantially complete loop.

The method also includes obtaining 1102 a voltage signal from at least two conductor segments 106 of the plurality of conductor segments 106. In configurations, obtaining 1102 the voltage signal from at least two conductor segments 106 of the plurality of conductor segments 106 includes obtaining multiple voltage signals over time from the at least two conductor segments 106 of the plurality of conductor segments 106. In such configurations, the method may also include integrating 1105, with an integrator element 102, the multiple voltage signals to produce an integrated output signal.

In configurations where multiple voltage signals over time are obtained, the method may also include integrating 1105, with a first integrator element 102, the multiple voltage signals of a first conductor segment 106 of the at least two conductor segments 106 to produce a first integrated output signal; integrating 1105, with a second integrator element 102, the multiple voltage signals of a second conductor segment 106 of the at least two conductor segments 106 to produce a second integrated output signal; and summing 1106, with a summing element 103, the first integrated output signal and the second integrated output signal.

In configurations where multiple voltage signals over time are obtained, the method may also include buffering 1104, with a first buffer element 509, the multiple voltage signals of a first conductor segment 106 of the at least two conductor segments 106 to produce a first buffered signal; buffering 1104, with a second buffer element 509, the multiple voltage signals of a second conductor segment 106 of the at least two conductor segments 106 to produce a second buffered signal; and integrating 1105, with an integrator element 102, the first buffered signal and the second buffered signal.

In configurations, positioning 1101 the Rogowski coil 101 to substantially surround the current-carrying conductor 104 may include positioning a first portion 1015 of the Rogowski coil 101 on a first side 1017 of a printed circuit board 1023; and positioning a second portion 1016 of the Rogowski coil 101 on a second side of the printed circuit board 1023, the printed circuit board 1023 being between the first portion 1015 of the Rogowski coil 101 and the second portion 1016 of the Rogowski coil 101, each of the first portion 1015 and the second portion 1016 including one or more conductor segments 106 of the plurality of conductor segments 106.

In configurations, positioning 1101 the Rogowski coil 101 to substantially surround the current-carrying conductor 104 may include cinching the plurality of conductor segments 106 such that a first portion 1015 of the plurality of conductor segments 106 forms the Rogowski coil 101 and a second portion 1016 of the plurality of conductor segments 106 is outside of the Rogowski coil 101. In such configurations, the method may further include detecting 1103, with a detector, a quantity of conductor segments 106 in the first portion 1015 of the plurality of conductor segments 106.

Current Monitor Combining a Shunt Resistor with a Rogowski Coil:

Large and rapidly changing currents, such as are common in switching power supplies and motor drives using Wide Band Gap semiconductors (and in lightning or other arc discharges), are notoriously difficult to measure accurately.

One approach often used is to place a series resistor (or “shunt”) in the current path, measure the voltage drop caused by the current, and divide by the resistance. This approach handles DC and lower frequencies well, but suffers at higher frequencies due to the inductive drop across the shunt, which exceeds the resistive drop for frequencies above a frequency fc:

$$V = R \cdot i + L \cdot \frac{di}{dt} \qquad {f}_{c} = \frac{R}{2 π \cdot L}$$

When measuring large currents, a relatively small shunt resistance R is needed to keep the voltage drop and power dissipation of the shunt within reason, which leads to objectionably low usable bandwidth fc.

The inductive drop can be eliminated by using a coaxial shunt, in which the resistive element is a cylinder, the return current passes through a larger and concentric outer cylinder, and the voltage measurement leads are routed out from the shunt inside the resistive cylinder. The symmetrical nature and the outer return current path ensure the magnetic field generated by the current circles between the shunt and the outer return path, leaving no magnetic field to impart an inductive drop on the measured voltage inside the shunt. Coaxial shunts eliminate measurement inductance (inductance included in the measured voltage drop), but require a longer current path through the shunt, thus increasing the insertion inductance (inductance inserted in the current path of the system under test). Even with no measurement inductance, coaxial shunts have limited bandwidth due to the skin effect of the shunt material. As frequency increases, the skin depth of electric current in a conductor decreases. Once the skin depth approaches the thickness of the resistive cylinder, a significantly lower portion of the current flows on the inside of the shunt, generating less resistive drop on the inside where the voltage is measured.

Another method to improve the usable bandwidth of a shunt is to add a canceling mutual inductance Mc in the lead dress of the voltage measurement leads of a conventional shunt:

$$V = R \cdot i + L \cdot \frac{di}{dt} - {M}_{C} \cdot \frac{di}{dt}$$

This minimizes the insertion inductance by not requiring a particular return current path but is trickier to implement because the return current path must still be known to determine lead placement to achieve cancelation (MC=L). The cancellation approach also suffers at high frequency due to skin effect: the current path through the shunt will shift in physical location as the skin depth approaches the shunt thickness, changing MC, L, & R.

Another current measurement approach is to sense the magnetic field along a closed loop encircling the current to be measured. A Rogowski coil senses the time derivative of this magnetic field; the voltage induced on the Rogowski coil can then be integrated to determine the current flow. Rogowski coils have the advantage of inherent isolation and relative ease of installation but cannot measure DC current. In fact, there is a trade-off between the low-frequency usable range and the high-frequency bandwidth of a Rogowski coil. Achieving low frequency coverage suggests a large mutual inductance between the coil and the current flow to maximize the coil voltage at low di/dt, whereas high bandwidth suggests a small self-inductance of the coil to minimize its time constant driving the load impedance of the integrator.

Embodiments of the disclosure generally include measuring current using a device that includes a combined shunt and Rogowski coil. The output of the combined shunt and Rogowski coil may feed through a compensating pole, such as a passive RC or LR filter. Some embodiments may connect the output(s) of the current measurement device to an isolated probe. The embodiments involve inserting a shunt having sense leads into the current path to be measured. The current measurement device includes a Rogowski coil wrapped at least partially around the shunt. The current measurement device is configured to combine the output signals from the shunt and the Rogowski coil. In some embodiments, the Rogowski coil is placed in series with the shunt sense leads.

This configuration generates a voltage:

$$V = R \cdot i + L \cdot \frac{di}{dt} - {M}_{C} \cdot \frac{di}{dt} + {M}_{R} \cdot \frac{di}{dt}$$

where MR is the mutual inductance of the Rogowski coil to the current in the shunt. The coil is attached to the shunt sense leads as much as practical opposite the current return path. This avoids the strongest magnetic field and thereby creates a canceling mutual inductance MC roughly equal to L. Unlike MC and L, MR of a uniform Rogowski coil surrounding a conductor does not change with skin-depth-induced shifts in the current path.

By making M_{c}≈L and M_{R}>>L−M, one can closely approximate the voltage as:

$$V = R \cdot i + {M}_{R} \cdot \frac{di}{dt}$$

This represents a single-zero frequency response, and can be flattened with a single-pole compensator, such as an RC filter with the same time constant, meaning RfCf=MR/R. At low frequencies, the R·i term dominates the shunt voltage, the compensating pole/RC filter is flat, and the shunt operates as a standard shunt. At high frequencies, the MR·di/dt term dominates the shunt voltage, the compensating pole acts as the integrator for the Rogowski coil, and the final output voltage remains flat. The output voltage of the compensating pole may be measured by an isolated probe to maintain the isolation benefit of a Rogowski coil. The compensating pole may take many forms, including various architectures of RC (Resistor Capacitor) filters, or LR (Inductor Resistor) filters.

Since DC and low frequencies are handled by the shunt action, the Rogowski coil inductance may be optimized for high-frequency operation. This allows for a design with smaller coil inductance and higher frequency coverage than a stand-alone Rogowski coil.

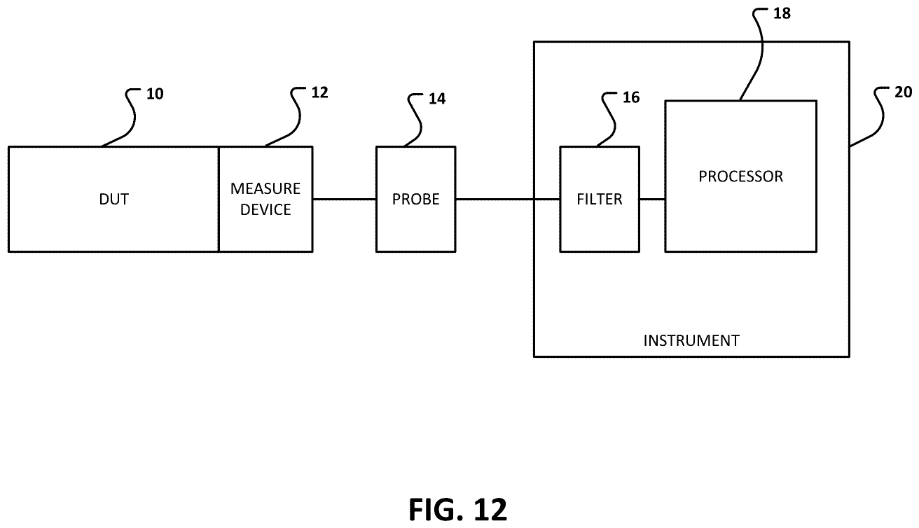

FIG. 12 shows a block diagram of a test and measurement system that includes a current measurement device in the form of a current shunt. One should note that this diagram shows several components not needed for the current measurement device but provides context for various embodiments of the device. In FIG. 12, a device under test (DUT) 10 has a current measurement device 12 attached to it. The current measurement device may comprise a built-in or “solder-down” component, or an attachable/detachable component. The DUT will generally connect to the test and measurement instrument 20 through one or more probes 14. In some instances, the one or more probes may comprise “isolated probes” in which the probe is galvanically isolated from the instrument. For higher voltage and frequency operations, including those with wide-band gap (WBG) devices, isolated probes allow for more accurate measurements and reduce shock hazard.

As will be discussed in more detail later, one or more filters at the instrument level may receive the output of the measurement device 12. These differ from the compensating pole filter discussed above. Filter 16 may take the form of a separate component, such as a digital signal processor, or analog filter, or may result from the processor 18 executing instructions to apply filtering to the incoming signal.

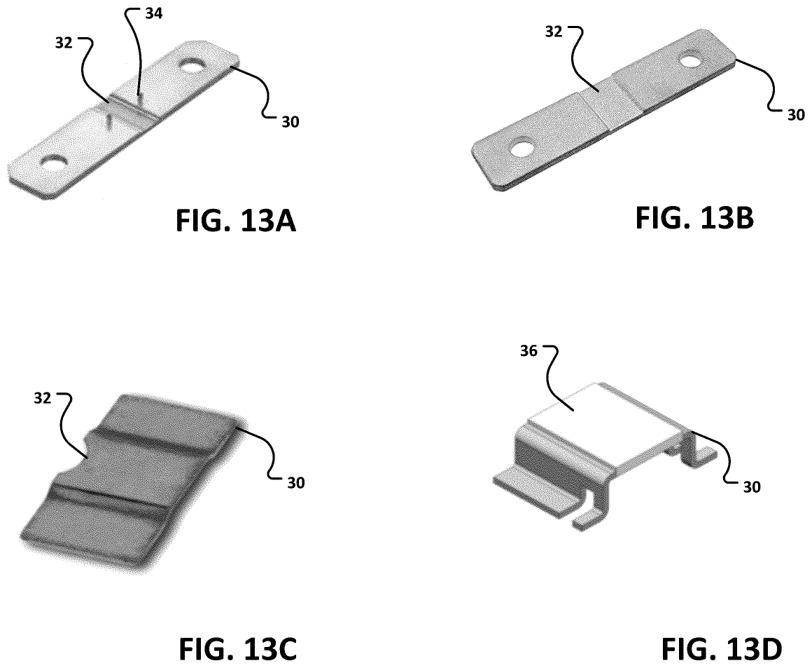

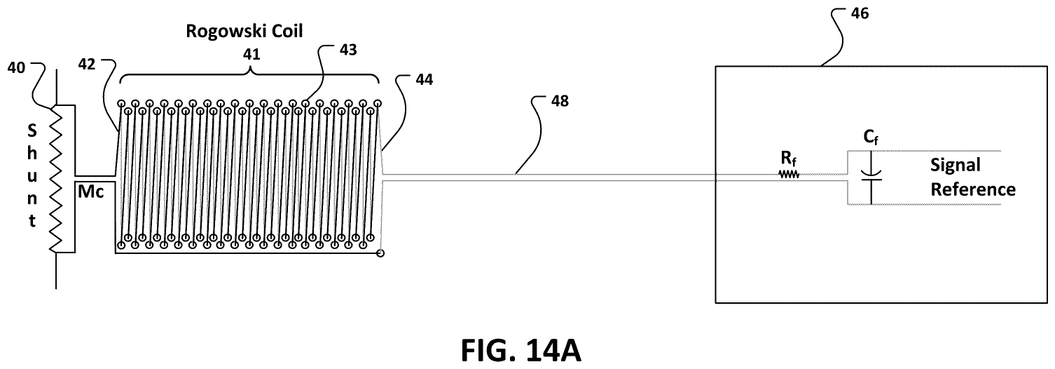

A Rogowski coil may be implemented in a flex circuit board of two (or more) layers, which can then be wrapped around and soldered onto a bulbar or surface-mount metal-alloy shunt 30 such as shown in FIGS. 13A-13D. The coil may wrap around the resistive portion 32 or 36 of the shunt 30, which may typically be made of manganin. In the embodiment of FIG. 13A, the sense leads such as 34 protrude from the shunt bar. FIGS. 13B-13D show different embodiments of the resistive portion 32 or 36 in the middle of copper portions.

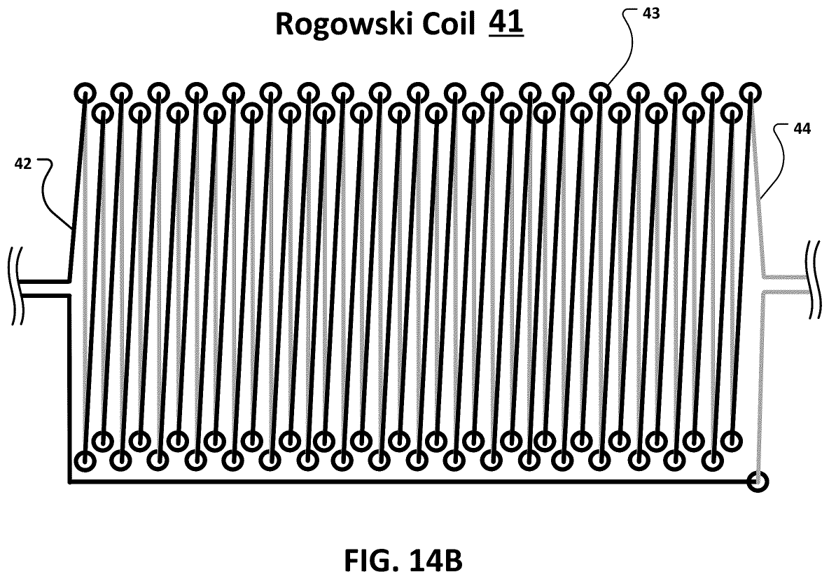

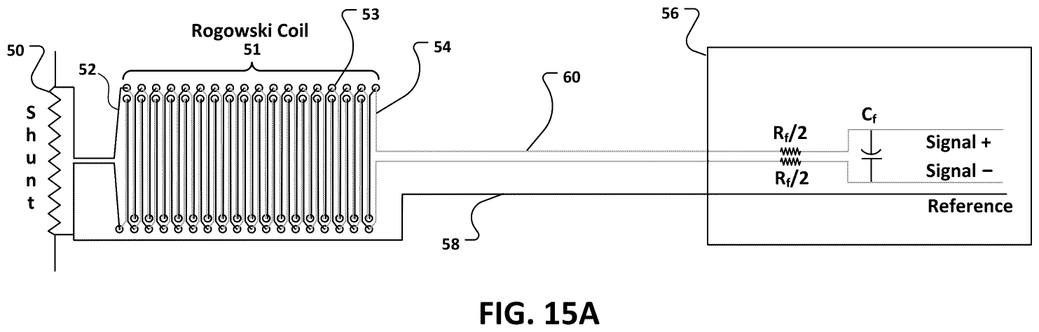

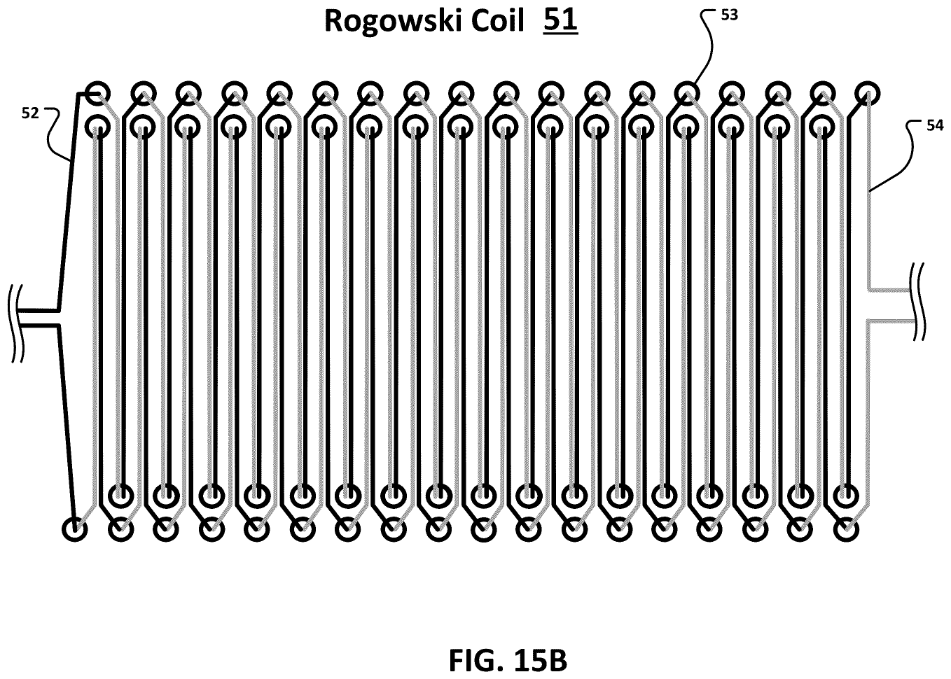

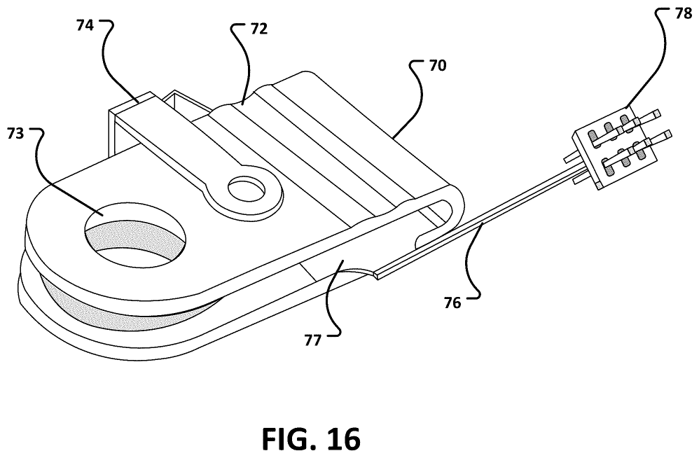

FIGS. 14A-14B and 15A-15B show a current measurement device that includes a combined shunt having sense leads and a Rogowski coil, in different embodiments. In a single-ended implementation shown in FIGS. 14A and 14B, the reference, which may comprise the shield of the isolated probe or isolation barrier, may tie to one side of the shunt 40. The Rogowski coil 41 may tie to the other side of the shunt, one end of R_{f} to the coil, the other end of R_{f} to C_{f} and the input of the probe, and the other end of C_{f} to the probe reference. FIG. 14B shows an enlarged view of the Rogowski coil 41 portion of the device.

One set of traces, designated by 42, are formed on one layer of the flex circuit nearest the shunt. The other set of traces, designated by 44, are formed on the opposite side of the layer of the flex circuit further from the shunt. In some embodiments, the flex circuit may have an insulating layer or flexible dielectric core between the layer having traces 42 and the layer having traces 44, and in some embodiments may also have insulating layers as the topmost and bottommost layers of the flex circuit. The traces 42 shown in black are connected to the traces 44 shown in gray by vias 43 in the flex circuit so that the traces and the vias form a continuous conductive Rogowski coil structure in the flex circuit. This causes the magnetic field looping the shunt to flow between the two sets of traces when the coil is wrapped around the shunt. The section of traces labeled Mc are placed as near to the shunt as possible and opposite the return current path to form the cancelling mutual inductance. The Rogowski coil section is then wrapped, at least partially, around the shunt. In one embodiment, a transmission line such as 48 connects to the coil. In another embodiment, the transmission line may connect to an isolation barrier, and in yet another embodiment, the isolation barrier exists in a probe head. The coil output may also connect to a fixed-time-constant single pole compensator 46. FIG. 14A shows an embodiment of this comprises an RC filter, having a filter resistor R_{f} and a filter capacitor C_{f}.

FIGS. 15A and 15B show a differential signaling embodiment. In a differential implementation, a shield portion of the isolation barrier, such as the shield of the isolated probe may tie to either side of the shunt. Half of the Rogowski coil 51 may be placed on each side of the shunt in order to feed a differential signal through the compensation pole 56. This may feed into R_{f}/2 on each side to C_{f} from side to side of the differential probe input. Alternatively, C_{f} may be replaced with two capacitors 2·C_{f} from each signal line to the reference. In another embodiment, the differential transmission line may be periodically “twisted” to cancel the pick-up of stray electro-magnetic fields. FIG. 15B shows an enlarged view of the Rogowski coil 51 portion of the device. The first traces 52 shown in black and the second traces 54 shown in gray are connected by vias 53 in the flex circuit.

FIG. 16 shows an embodiment of the shunt having the Rogowski coil in a busbar embodiment in which the Rogowski coil is sandwiched within a folded busbar shunt. The busbar shunt 70 has a resistive portion 72. The shunt folds in half to lower insertion inductance and put the two screw terminals such as 73 on the same axis, with a flex circuit 77 between the folded halves. One sense lead 74 wraps around the top to connect to one side of the shunt and the other sense lead wraps around underneath, hidden in this view, to connect to the other side of the shunt. A square-pin connector 78 at the end of a portion of the flex 76 connects this to the isolation barrier or probe head. The traces on the flex for the coil, and the compensating pole components are not shown.

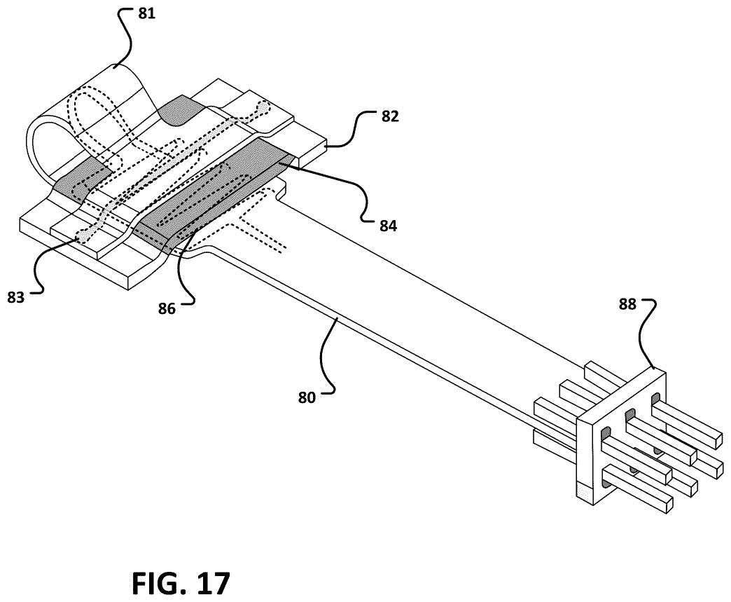

FIG. 17 shows an embodiment of a surface-mount shunt with a flex circuit 80 underneath, between the shunt and the return path in the circuit board on which the shunt will be mounted. The shunt comprises the metal portion 82 and the resistive portion 84. Each sense lead such as 83 wraps around the top of the shunt, by way of portion 81 of flex circuit 80, and connects on either side of the shunt to each metal portion such as 82. In this picture, the flex circuit traces forming the Rogowski coil are shown at 86. Although not shown, those traces would continue up the flex circuit 80 to the compensating pole components and the square-pin connector 88.

Many modifications and variations exist. For example, the filter resistor R_{f} may serve as termination for a transmission-line between the shunt/coil and the filter, allowing the probe head to be placed some distance from the shunt while still maintaining high bandwidth. This allows the shunt to be placed in very close proximity to the load without providing extra room for the probe head, thus minimizing insertion inductance.

Since the Rogowski coil connects directly to the shunt around which it wraps, it does not need high-voltage insulation, and may be placed in very close proximity to the shunt. This may further reduce coil inductance by keeping the coil as short as possible.

If the return-current path is well-defined, such as for the surface-mount shunt over a return plane layer within a PCB, the Rogowski-coil self-inductance can be further minimized by shortening the coil to cover the space between the shunt and the return path only, rather than fully encircling the shunt. The magnetic field is strongest within the current loop, so this placement will achieve almost as much mutual inductance as a complete encirclement, but with considerably less self-inductance. This arrangement also avoids vias, used to implement the coils in a flex circuit, in the tight bend sections around the sides of the shunt, reducing the chance of via cracking.

The compensating filter time constant may be matched to the M_{R}/R time constant with any combination of methods. For instance, in one embodiment, the shunt and the Rogowski coil may be built together as a single unit with appropriate component values. This may take the form shown in FIG. 16 or 17, as examples.

Another embodiment provides a selection of fixed-time-constant filters appropriate for given shunt-Rogowski-coil pairs. This may be implemented in the filter blocks 46 and 56 of FIGS. 14A and 15A, respectively. In yet another embodiment, the filter block may provide one or more programmable filters, such as using FETs to switch capacitors in a capacitor DAC for C_{f}. The response pole due to the load of the filter resistance R_{f} on the Rogowski coil's self-inductance may be compensated with a corresponding zero by placing some resistance in series with C_{f}. In yet another embodiment, the Rogowski loop area and/or pitch may be tapered along the length of the coil, such that the mutual inductance MR may be adjusted by sliding the appropriate section of the tapered coil underneath the shunt.

Regarding the system shown in FIG. 12, one can also work with the acquired signal from the probe as it enters the instrument to adjust for differences between the time constant of the compensating pole and M_{R}/R. For example, filter 16, which is applied after the signal is acquired by the probe, may take form of a DSP pole-zero filter applied to the acquired waveform to cancel any remaining filter time constant mismatch. In addition, if the M_{R}·di/dt term does not sufficiently dominate the R·I term at the frequency where skin effect begins significantly changing the effective resistance R, the filter 16 may comprise an analog and/or DSP filter applied to compensate the resultant error in the cross-over region between shunt- and Rogowski-dominated response.

In this manner, a current measuring device comprises both a shunt and a Rogowski coil. In the embodiments here, the Rogowski coil is not in parallel or series with the current path of the shunt, but wraps around the shunt to minimize the distance, and therefore the inductive drop, caused by the shunt and coil.

### Examples

Illustrative examples of the disclosed technologies are provided below. A particular configuration of the technologies may include one or more, and any combination of, the examples described below.

Example 1 includes a current sensor configured to measure current in a current-carrying conductor, the current sensor comprising a Rogowski coil having plurality of conductor segments, the plurality of conductor segments positionable to form a substantially complete loop, in which a first conductor segment of the plurality of conductor segments is electrically isolated from a second conductor segment of the plurality of conductor segments.

Example 2 includes the current sensor of Example 1, further comprising an integrator element configured to receive an output from the first conductor segment of the plurality of conductor segments.

Example 3 includes the current sensor of any of Examples 1-2, further comprising an individual integrator element for each conductor segment of the plurality of conductor segments.

Example 4 includes the current sensor of Example 3, further comprising a summing element configured to produce a sum of outputs of the individual integrator elements.

Example 5 includes the current sensor of Example 4, in which the summing element is a summing amplifier.

Example 6 includes the current sensor of any of Examples 1-5, further comprising an integrator element configured to receive an output from more than one conductor segment of the plurality of conductor segments.

Example 7 includes the current sensor of any of Examples 1-6, in which an output lead of the first conductor segment is on a same side of the Rogowski coil as an output lead of the second conductor segment.

Example 8 includes the current sensor of any of Examples 1-7, in which the first conductor segment of the plurality of conductor segments is flexibly joined to an adjacent conductor segment of the plurality of conductor segments.

Example 9 includes the current sensor of any of Examples 1-7, in which the first conductor segment of the plurality of conductor segments is mechanically separable from an adjacent conductor segment of the plurality of conductor segments.

Example 10 includes the current sensor of any of Examples 1-9, in which the first conductor segment of the plurality of conductor segments is galvanically isolated from another conductor segment of the plurality of conductor segments.

Example 11 includes the current sensor of any of Examples 1-10, further comprising an individual buffer element for each conductor segment of the plurality of conductor segments.

Example 12 includes the current sensor of Example 11, further comprising an integrator element configured to receive an output from more than one of the individual buffer elements.

Example 13 includes the current sensor of any of Examples 1-12, in which a quantity of conductor segments comprising the Rogowski coil is adjustable.

Example 14 includes the current sensor of Example 13, further comprising a cinch mechanism to separate a first portion of conductor segments comprising the Rogowski coil and a second portion of conductor segments outside of the Rogowski coil, the first portion of conductor segments and the second portion of conductor being coupled together.

Example 15 includes the current sensor of Example 14, further comprising a detector configured to detect the quantity of conductor segments that are forming the Rogowski coil.

Example 16 includes the current sensor of Example 15, in which the detector comprises at least one of a mechanical switch or an optical switch to detect the quantity of conductor segments that are forming the Rogowski coil.

Example 17 includes the current sensor of any of Examples 1-16, in which each conductor segment of the plurality of conductor segments is in a common housing.

Example 18 includes the current sensor of any of Examples 1-16, in which the first conductor segment of the plurality of conductor segments is in a first housing and the second conductor segment of the plurality of conductor segments is in a second housing that is separate from the first housing.

Example 19 includes a method of using a current sensor to measure current in a current-carrying conductor, the method comprising: positioning a Rogowski coil to substantially surround a current-carrying conductor, the Rogowski coil having plurality of conductor segments, the plurality of conductor segments being arranged to form a substantially complete loop; and obtaining a voltage signal from at least two conductor segments of the plurality of conductor segments.

Example 20 includes the method of Example 19, in which obtaining the voltage signal from at least two conductor segments of the plurality of conductor segments includes obtaining multiple voltage signals over time from the at least two conductor segments of the plurality of conductor segments.

Example 21 includes the method of Example 20, further comprising integrating, with an integrator element, the multiple voltage signals to produce an integrated output signal.

Example 22 includes the method of Example 21, further comprising buffering, with a buffer element, the multiple voltage signals prior to integrating the multiple voltage signals.

Example 23 includes the method of any of Examples 20-22, further comprising: integrating, with a first integrator element, the multiple voltage signals of a first conductor segment of the at least two conductor segments to produce a first integrated output signal; integrating, with a second integrator element, the multiple voltage signals of a second conductor segment of the at least two conductor segments to produce a second integrated output signal; and summing, with a summing element, the first integrated output signal and the second integrated output signal.

Example 24 includes the method of any of Examples 19-23, in which positioning the Rogowski coil to substantially surround the current-carrying conductor comprises: positioning a first portion of the Rogowski coil on a first side of a printed circuit board; and positioning a second portion of the Rogowski coil on a second side of the printed circuit board, the printed circuit board being between the first portion of the Rogowski coil and the second portion of the Rogowski coil, each of the first portion and the second portion including one or more conductor segments of the plurality of conductor segments.

Example 25 includes the method of any of Examples 19-23, in which positioning the Rogowski coil to substantially surround the current-carrying conductor comprises cinching the plurality of conductor segments such that a first portion of the plurality of conductor segments forms the Rogowski coil and a second portion of the plurality of conductor segments is outside of the Rogowski coil.

Example 26 includes the method of Example 25, further comprising detecting, with a detector, a quantity of conductor segments in the first portion of the plurality of conductor segments.

Example 27 is a current measurement device, comprising: a shunt having sense leads, the shunt configured to be located in a current path for a current to be measured; and a Rogowski coil at least partially wrapped around the shunt, the current measuring device configured to combine signals from the shunt and the Rogowski coil.

Example 28 is the current measurement device of Examples 27, wherein the current measuring device is configured to combine the signals by placing the Rogowski coil in series with the sense leads.

Example 29 is the current measurement device of either of Examples 27 or 28, wherein the current measuring device is configured to combine the signals from the shunt and the Rogowski coil by adding the signals.

Example 30 is the current measurement device of Example 29, further comprising a compensating pole electrically connected to the Rogowski coil.

Example 31 is the current measurement device of Example 30, further comprising a filter applied to an output of the compensating pole, the filter configured to compensate for errors in a cross-over region between a shunt-dominated response and a Rogowski-coil-dominated response when a skin effect begins to change an effective resistance.

Example 32 is the current measurement device of Example 31, wherein the filter comprises an analog filter.

Example 33 is the current measurement device of Example 31, wherein the filter comprises a digital signal processing filter.

Example 34 is the current measurement device of Example 30, wherein a digital signal processing filter is configured to correct for a mismatch between time constants of the Rogowski coil and the compensating pole.

Example 35 is the current measurement device of Example 30, wherein the compensating pole comprises an LR filter.

Example 36 is the current measurement device of Example 30, wherein the compensating pole comprises an RC filter having at least one filter resistor and at least one filter capacitor.

Example 37 is the current measurement device of Example 36, wherein the at least one filter capacitor comprises two filter capacitors and the at least one filter resistor comprises two filter resistors, each filter capacitor connected between one of the two filter resistors and a reference.

Example 38 is the current measurement device any of Example 36, further comprising a resistance in series with the at least one filter capacitor.

Example 39 is the current measurement device any of Examples 27 through 38, wherein the current measurement device is configured to produce a single-ended output signal.

Example 40 is the current measurement device any of Examples 27 through 39, wherein the current measurement device is configured to produce a differential output signal.

Example 41 is the current measurement device any of Examples 27 through 39, wherein the Rogowski coil at least partially covers a space between the shunt and a current return path.

Example 42 is the current measurement device any of Examples 27 through 40, further comprising one or more programmable filters connected to the Rogowski coil.

Example 43 is the current measurement device of Example 42, wherein the one or more programmable filters comprise a switchable capacitor digital-to-analog converter (DAC).

Example 44 is the current measurement device any of Examples 27 through 43, wherein the shunt comprises a bulbar shunt folded in half, and the Rogowski coil is positioned between the halves, with one sense lead wrapped around a top of the shunt to connect to one side of the shunt and another sense lead wrapped around a bottom of the shunt to connect to another side of the shunt.

Example 45 is the current measurement device any of Examples 27 through 44, wherein the shunt comprises a surface mount shunt and the Rogowski coil is positioned underneath the shunt with the sense leads wrapped around to a top of the shunt and connected on either end of the shunt.

Example 46 is the current measurement device of Example 41, wherein the Rogowski coil is tapered and slidable between the shunt and return current path to tune mutual inductance of the Rogowski coil and the shunt.

Example 47 is the current measurement device any of Examples 27 through 46, wherein the shunt and the Rogowski coil comprise a single unit.

Example 48 is a current measurement device, comprising: a shunt having sense leads configured to be located in a current path for a current to be measured; a Rogowski coil in series with the sense leads and at least partially wrapped around the shunt; a compensating pole connected to the Rogowski coil; and an isolation barrier connected to the compensating pole.

Example 49 is the current measurement device of Example 48, wherein a time constant of the compensating pole comprises an RC filter matched to a mutual inductance of the Rogowski coil to current in the shunt divided by an effective resistance.

Example 50 is the current measurement device of either of Examples 48 or 49, wherein the compensating pole comprises a selection of fixed time-constant RC filters selectable based upon a particular combination of the shunt and the Rogowski coil.

Example 51 is the current measurement device of any of Examples 48 through 50, wherein the isolation barrier is part of an isolated probe connected to a test and measurement device.

Aspects may operate on a particularly created hardware, on firmware, digital signal processors, or on a specially programmed general purpose computer including a processor operating according to programmed instructions. The terms “controller” or “processor” as used herein are intended to include microprocessors, microcomputers, ASICs, and dedicated hardware controllers. One or more aspects may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, RAM, etc. As will be appreciated by one of skill in the art, the functionality of the program modules may be combined or distributed as desired in various configurations. In addition, the functionality may be embodied in whole or in part in firmware or hardware equivalents such as integrated circuits, field programmable gate arrays (FPGA), and the like. Particular data structures may be used to more effectively implement one or more aspects of the disclosed systems and methods, and such data structures are contemplated within the scope of computer executable instructions and computer-usable data described herein.

The previously described versions of the disclosed subject matter have many advantages that were either described or would be apparent to a person of ordinary skill. Even so, all of these advantages or features are not required in all versions of the disclosed apparatus, systems, or methods.

Additionally, this written description makes reference to particular features. It is to be understood that the disclosure in this specification includes all possible combinations of those particular features. For example, where a particular feature is disclosed in the context of a particular example configuration, that feature can also be used, to the extent possible, in the context of other example configurations.

Also, when reference is made in this application to a method having two or more defined steps or operations, the defined steps or operations can be carried out in any order or simultaneously, unless the context excludes those possibilities.

Furthermore, the term “comprises” and its grammatical equivalents are used in this application to mean that other components, features, steps, processes, operations, etc. are optionally present. For example, an article “comprising” or “which comprises” components A, B, and C can contain only components A, B, and C, or it can contain components A, B, and C along with one or more other components.

Although specific example configurations have been described for purposes of illustration, it will be understood that various modifications may be made without departing from the spirit and scope of the disclosure.

I (or we) claim:

1. A current sensor configured to measure current in a current-carrying conductor, the current sensor comprising:
a shunt configured to be placed in series with the current-carrying conductor; and
a Rogowski coil including at least one conductor segment;
in which the shunt and the Rogowski coil are coupled to produce an output signal representing the current in the current-carrying conductor.

2. The current sensor of claim 1, further comprising a pair of sense leads coupled to the shunt, in which a conductor segment of the Rogowski coil is coupled to one of the sense leads.

3. The current sensor of claim 1, further comprising an integrator element configured to receive an output from a conductor segment of the Rogowski coil

4. The current sensor of claim 3, in which the integrator element comprises a compensating pole filter.

5. The current sensor of claim 1, in which the Rogowski coil includes a plurality of conductor segments.

6. The current sensor of claim 5, in which a first conductor segment is electrically isolated from a second conductor segment.

7. The current sensor of claim 5, further comprising an individual integrator element for each conductor segment of the plurality of conductor segments.

8. The current sensor of claim 7, in which each individual integrator element comprises a compensating pole filter.

9. The current sensor of claim 7, further comprising a summing element configured to produce a sum of outputs of the individual integrator elements.

10. The current sensor of claim 5, further comprising an integrator element configured to receive an output from more than one conductor segment of the plurality of conductor segments.

11. The current sensor of claim 10, in which the integrator element comprises a compensating pole filter.

12. The current sensor of claim 1, in which a conductor segment of the Rogowski coil at least partially encompasses the shunt.

13. The current sensor of claim 1, further comprising an individual buffer element for each conductor segment of the Rogowski coil.

14. The current sensor of claim 13, further comprising an integrator element configured to receive an output from one or more individual buffer elements.

15. The current sensor of claim 14, in which the integrator element comprises a compensating pole filter.

16. The current sensor of claim 1, further comprising a probe connector for electrically and mechanically coupling the current sensor to a test and measurement probe.

17. The current sensor of claim 1, further comprising an instrument connector for electrically and mechanically coupling the current sensor to a test and measurement instrument.

18. The current sensor of claim 1, in which a first conductor segment of the Rogowski coil has an inductance different than an inductance of a second conductor segment.

19. The current sensor of claim 1, in which a first conductor segment of the Rogowski coil has an optimized current measurement frequency range different than an optimized current measurement frequency range of a second conductor segments.

20. A current sensor configured to measure current in a current-carrying conductor, the current sensor comprising a Rogowski coil having a plurality of conductor segments, the plurality of conductor segments positionable to form a substantially complete loop around the current-carrying conductor.
